(19) United States
(12) Patent Application Publication
(10) Pub. No.: US 2004/0203187 A1
(43) Pub. Date: Oct. 14, 2004

(54) Method for manufacturing semiconductor wafer

(76) Inventors: Kazuma Sekiya, Tokyo (JP); Kazuhisa Arai, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 10/819,179

(22) Filed: Apr. 7, 2004

(30) Foreign Application Priority Data
Apr. 8, 2003 (JP) 2003-104038

(51) Int. Cl. H01L 21/50

(52) U.S. Cl. 438/106

(57) ABSTRACT

In order to form bumps easily on bonding pads with uniform bump head height in case of manufacturing a semiconductor wafer to form bumps thereon by wire bonding, a method for manufacturing a semiconductor wafer comprises the steps of forming bumps on bonding pads formed on a surface of a semiconductor wafer by wire bonding, forming a resin layer by coating a resin on the surface in a manner of burying the bumps, and surfacing the bumps by grinding the resin layer and making the bump head height uniform.

### BACKGROUND OF THE INVENTION

1. Field of the Invention

The present invention relates to a method for manufacturing a semiconductor wafer formed with bumps on the surface.

2. Related Art

The semiconductor wafer, formed with a plurality of integrated circuits such as ICs or LSIs, is divided into individual semiconductor chips by a dicer or the like. Those are packaged and used on electronic appliances in various kinds. In order to reduce the size and weight of the electronic appliance, there has been developed and placed in practical application a technology of packaging a semiconductor chip in a package in a chip size, called CSP.

The CSP is formed by forming metal bumps of gold, silver, copper or the like made in a height of 50-100 μm on the bonding pads formed on the individual integrated circuits of an undivided semiconductor wafer by the method using wire bonding, called stud bump bonding, for example (see JP-A-2000-332048, for example), and dividing the semiconductor wafer, after coated and protected by a resin such as an epoxy resin on the circuit surfaces, into individual semiconductor chips (see JP-A-2000-173954, for example) for each circuit by a dicer or the like. The bumps are connected to terminals of a printed board through solder or the like, whereby the CSP is mounted on the printed board.

However, there is a problem that the bump has a diameter of approximately 50-100 μm wherein, during stud bump bonding, a whisker-like projection is formed at the head of a bump, thus resulting in non-uniform head height.

In order to make uniform the head height of bumps, there is a need to polish the bump head for a considerable time by means of CMP (Chemical Mechanical Polishing), posing a problem of reducing the productivity.

Accordingly, in the case of manufacturing a semiconductor wafer to form bumps thereon by wire bonding, there is a problem in easily forming bumps on bonding pads and making the bump head height uniform by an efficient method.

### SUMMARY OF THE INVENTION

The present invention provides, as concrete means for solving the above problem, a method for manufacturing a semiconductor wafer comprising: a bump forming step of forming bumps on bonding pads formed on a surface of a semiconductor wafer by wire bonding; a resin coating step of forming a resin layer by coating a resin on the surface of the semiconductor wafer in a manner of burying the bumps; and a grinding step of surfacing the bumps by grinding the resin layer.

In the method for manufacturing a semiconductor wafer thus structured, after forming bumps by wire bonding, a resin layer is formed in a manner of burying the bumps, so that the bump can be surfaced by grinding the resin layer. Accordingly, it is possible to form bumps in a brief time and to make the bump head height uniform by an efficient method.

### BRIEF DESCRIPTION OF THE DRAWING

FIG. 1 is a plan view showing a semiconductor wafer formed with bonding pads;

FIGS. 2A to 2D are sectional views showing a manner of forming a bump by wire bonding;

FIG. 3 is a sectional view showing a semiconductor wafer after completing a bump forming process;

FIG. 4 is a sectional view showing a semiconductor wafer after completing a resin coating process;

FIG. 5 is a perspective view showing an example of a grinding device to be used in a grinding process; and

FIG. 6 is a sectional view showing a semiconductor wafer after completing the grinding process.

### DETAILED DESCRIPTION OF PREFERRED EMBODIMENT

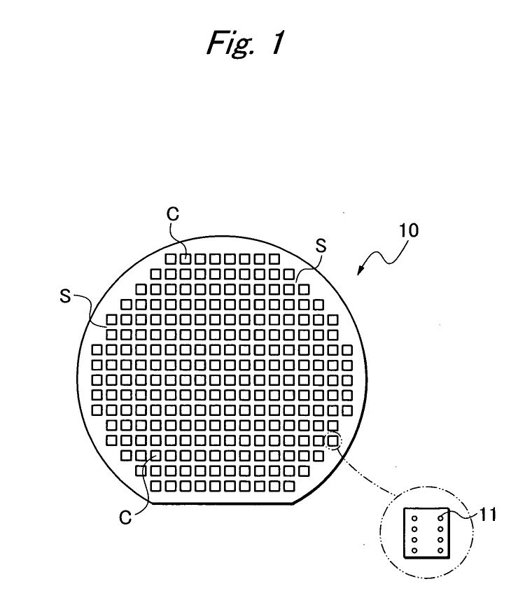

With reference to FIGS. 1 to 6, an embodiment of the present invention is explained. FIG. 1 shows a semiconductor wafer 10 having a surface on which circuits C are formed in respective regions sectioned by streets S. Each of the circuits C is formed with a plurality of bonding pads 11, as shown by magnification in FIG. 1. These bonding pads 11 are electrodes made by a metal coat formed on the surface of the semiconductor wafer 10.

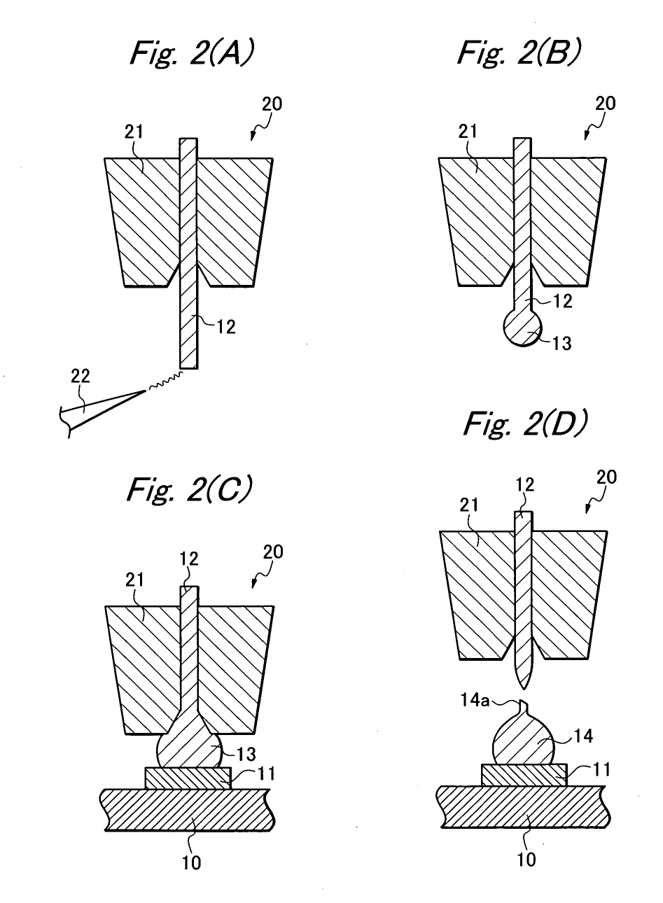

On the bonding pad 11, bumps are formed by the use of a wire bonder 20 shown for example in FIGS. 2A to 2D. When using the wire bonder 20, a wire 12 formed for example of gold is projected downward out of the fine hole formed through a capillary 21, as shown in FIG. 2A. By generating an electric discharge between an electric torch 22 and the wire 12, a ball 13 is formed at the tip of the wire 12 as shown in FIG. 2B.

Then, as shown in FIG. 2C, the capillary 21 is descended to bring the ball 13 into pressure-contact with the bonding pad 11, in which state ultrasonic vibration is applied from the capillary 21 or thermal compression is carried out. As shown in FIG. 2D, the wire 12 is torn off by raising the capillary 21, whereby a bump 14 is formed by the wire (bump forming process). By thus carrying out the bump forming process, the bumps can be formed in a shorter time than the case of plating or the like. Incidentally, a projection 14a is formed, as a cut end of break, at the top end of the bump 14. The projections 14a are different in height between the bumps.

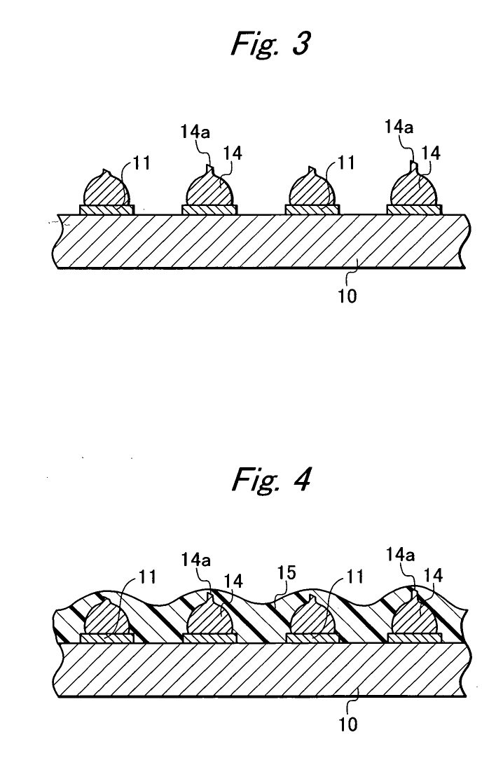

After bumps 14 have been formed on all the bonding pads 11 as shown in FIG. 3, a resin, e.g. an epoxy resin, is coated to bury all the bumps 14 thereby forming a resin layer 15 (resin coating process) as shown in FIG. 4. In forming the resin layer 15, a spin coater can be used.

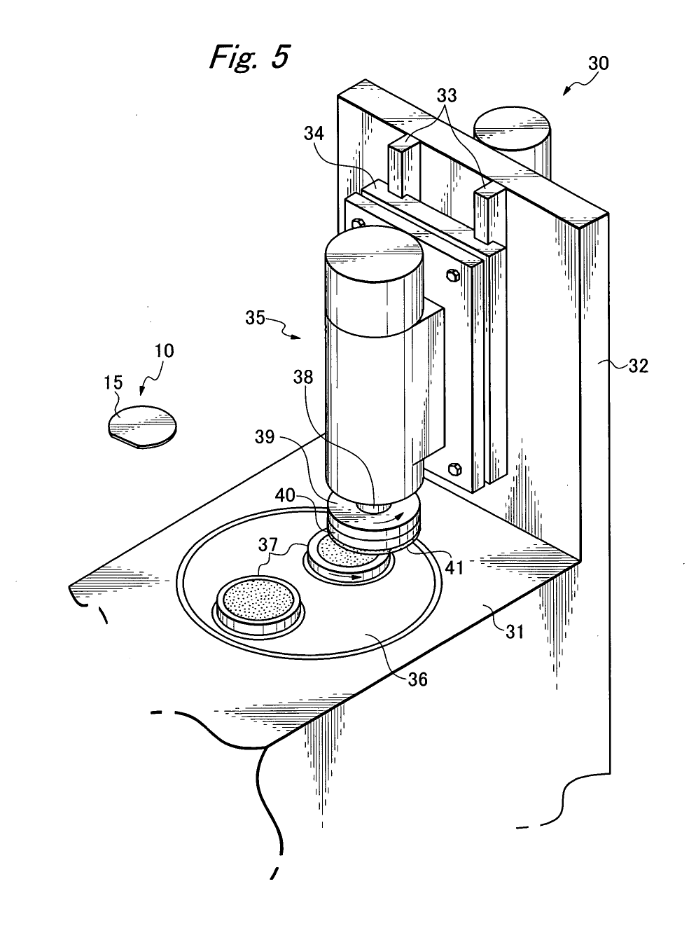

After forming the resin layer 15, the resin layer 15 is ground by the use of a grinding device 30 for example shown in FIG. 5, thereby surfacing the bumps 14. On the grinding device 30, a wall part 32 rises from an end of a base 31. A pair of rails 33 is vertically arranged on the inner surface of the wall part 32. By vertically moving a support plate 34 while being guided on the rail 33, a grinding means 35 arranged on the support plate 34 is structurally moved up and down. Meanwhile, a turntable 36 is rotatably arranged on the base 31. Furthermore, the turntable 36 rotatably sustains thereon a plurality of chuck tables 37 for supporting the semiconductor wafers 10.

The grinding means 35 has a mounter 39 attached to the tip end of a spindle 38 having a vertical axis, and a grinding wheel 40 is fixed to the lower of the mounter. A grindstone 41 is secured on the underside of the grinding wheel 40. The grindstone 41 is structurally rotated with rotation of the spindle 38. Note that the grinding means may be a bite fixed on the underside of the grinding wheel 40.

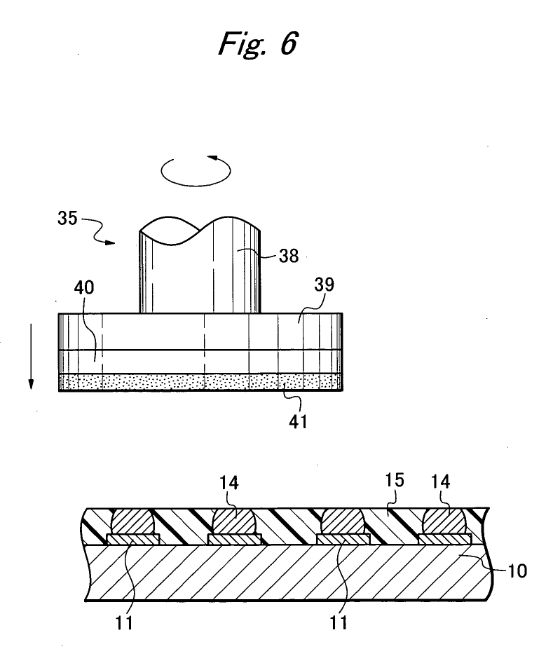

When grinding the resin layer 15 coated over the surface of the semiconductor wafer 10 by the use of the grinding device 30, the semiconductor wafer 10 is held with its resin layer 15 faced up on the chuck table 37 and positioned immediately below the grinding means 35. The spindle 38 is rotated and the grinding means 35 is lowered. By rotating the spindle 38, the grindstone 41 is rotated. The rotating grindstone 41 goes into contact with and exerting pressure to the resin layer 15 formed on the surface of the semiconductor wafer 10. Due to this, the resin layer 15 is ground by the grindstone 41. By thus carrying out a grinding in a predetermined amount, the bumps 14 are surfaced, as shown in FIG. 6 (grinding process). In this case, even in case there are variations in height between the bumps 14, the heads are made uniform in height by grinding. Furthermore, the bump 14 head is made in flush with the upper surface of the resin layer 15. Accordingly, smooth connection is possible to printed board terminals. Meanwhile, because the bumps 14 can be surfaced and aligned at heads by grinding instead of CMP, process is efficient and productivity is improved.

The semiconductor wafer 10 thus formed with bumps is cut lengthwise and widthwise along the streets shown in FIG. 1, thus made into semiconductor chips based on each circuit. The bumps formed on the individual semiconductor chip are connected to the terminals of a printed board to be mounted in an electronic appliance in various kinds, thus offering the functions of the chip. The uniform bump height enables positive connection with terminals without causing poor contact or the like, making it possible to improve the reliability of the apparatus overall.

As explained above, according to the method for manufacturing a semiconductor wafer of the present invention, after forming bumps by wire bonding, a resin layer is formed to bury the bumps, so that the bumps can be surfaced and made uniform at the heads thereof by grinding the resin layer. Accordingly, it is possible to form bumps in a brief time and to make the bump head height uniform by an efficient method. Therefore, it is possible to efficiently manufacture a quality semiconductor wafer.

What is claimed is:

1. A method for manufacturing a semiconductor wafer comprising:
a bump-forming step of forming bumps on bonding pads formed on a surface of a semiconductor wafer by wire bonding;
a resin coating step of forming a resin layer by coating a resin on the surface in a manner of burying the bumps; and
a grinding step of surfacing the bumps by grinding the resin layer.
